(19) United States
(12) Patent Application Publication
(10) Pub. No.: US 2023/0049054 A1
(43) Pub. Date: Feb. 16, 2023

(54) METHOD OF MANUFACTURING MICROFLUIDIC DEVICE USING TRANSFER FILM AND LAB-ON-PAPER PLATFORM MANUFACTURED BY MANUFACTURING METHOD THEREOF

(71) Applicant: AItheNutriGene Co., Seongnam-si (KR)

(72) Inventors: Chang Soo Lee, Daejeon (KR); Sung kweon Kim, Anyangsi (KR); Hyun Pyo Kim, Seoul (KR)

(21) Appl. No.: 17/883,271

(22) Filed: Aug. 8, 2022

(30) Foreign Application Priority Data
Aug. 11, 2021 (KR) 10-2021-0106241

(51) Int. Cl. B01L 3/00

(52) U.S. Cl. CPC B01L 3/502707; B01L 2200/12; B01L 2300/126; B01L 2300/165; B01L 2300/0887; B01L 2400/0406

(57) ABSTRACT

The present disclosure relates to a method of manufacturing a microfluidic device, which may precisely form a channel having a desired shape within one substrate using a wax regardless of a shape of a hydrophilic porous substrate, and more specifically, to a method of manufacturing a microfluidic device in which a microchannel is formed by a wax within one hydrophilic porous substrate, the method including: an operation of stacking and then heat-treating a transfer film on which a mirror image of a wax pattern is formed to form a microchannel and the substrate.

### CROSS-REFERENCE TO RELATED APPLICATIONS

This application claims the priority of the Korean Patent Applications NO 10-2021-0106241 filed on Aug. 11, 2021, in the Korean Intellectual Property Office, the disclosure of which is incorporated herein by reference.

### BACKGROUND

### (a) Technical Field

The present disclosure relates to a method of manufacturing a microfluidic device capable of precisely forming a channel of a desired shape in a single substrate using wax regardless of a shape of a hydrophilic porous substrate.

### (b) Background Art

A paper has a porous/fibrous structure, and may store or fix chemical substances, and move fluids by a capillary phenomenon even without a separate pump, and thus may be used as a microfluidic device that requires the movement of microfluid. Although described as a representative term of “paper” in this specification, this is a hydrophilic porous material, and the same technique using hydrophobic wax may be applied to any material capable of lateral flow of the fluid by the capillary phenomenon, and the paper includes materials such as paper, porous metal mesh, nonwoven fabric, cellulose, chitosan, hydrophilic polymer membrane such as PLA (polylactic acid), sponge, fabric but is of course not limited thereto.

Since the paper may be variously modified by printing, coating, and impregnating methods, samples may be distributed to several separate spaces so that multiple analyses may be performed simultaneously in a single chip. In addition, the paper has a mechanical flexibility, may be analyzed even with a small volume of sample due to the thickness of several tens to hundreds of micrometers, and has excellent portability due to light and easy movement. Accordingly, the paper is suitable for field application, and may be disposed of by incineration, so that it is possible to easily remove hazardous waste. Above all, the paper may be attracting attention as an ideal platform for ultra-low-cost analysis equipment because it may be manufactured at low cost. Accordingly, the paper may be applied in various fields including health examination, environmental monitoring, immunoassay, and food safety analysis.

As a paper-based diagnostic device, a dipstick type, in which a color change is observed by immersing a paper in a sample, was first commercialized in the 1960s and is representatively and widely used for urinalysis. A paper-based microfluidic device using a lateral flow due to a porous nature has been rapidly expanded and used to food and environmental fields since it started to be used for pregnancy diagnosis using immunoassay in the 1980s later than the 1960s.

The paper-based microfluidic device may be classified into a one-dimensional microfluidic device designed to allow fluid to move in only one direction depending on a flow direction of the fluid, a two-dimensional microfluidic device designed to move in multiple directions within the same plane that is a horizontal direction, and a three-dimensional microfluidic device that moves vertically as well as horizontally (see FIG. 1). Compared to the one-dimensional and two-dimensional microfluidic devices, the three-dimensional microfluidic device may form a channel with a complicated structure, and thus may perform simultaneous multiple analysis in an intensive space, and perform quantitative analysis by more advanced colorimetric analysis. The advanced colorimetric analysis is an analysis method that expresses the concentration of a substance to be detected in a solution as the number of color-changing dots. The conventional colorimetric analysis method may perform only the qualitative analysis or measure only an approximate amount, and thus necessarily requires an external electronic analysis device to precisely analyze the change in the color of the reagent for quantitative analysis, whereas the advanced colorimetric analysis method may perform the quantitative analysis even without external electronic analysis device, thereby doubling the usability as a digital analysis device.

The paper-based microfluidic device is manufactured by forming patterns of hydrophobic and hydrophilic regions on the paper using lithography, wax printing, or etching. Korean Patent Application Laid-Open No. 10-2010-0127301 discloses a method of manufacturing a three-dimensional paper-based microfluidic device using a paper and a double-sided tape. A manufacturing process will be described with reference to FIG. 2 as follows. First, patterns of hydrophobic and hydrophilic regions are formed on each paper to have a desired channel shape when a plurality of papers is stacked (210). For forming the pattern, a method such as lithography or wax printing may be appropriately used, similarly to the two-dimensional paper-based microfluidic device. The paper of each layer on which the pattern is formed is connected by using a hydrophobic double-sided adhesive tape, and first, when the paper of each layer is bonded, a hole is perforated in the double-sided adhesive tape so that the fluid may flow along the hydrophilic region (paper) of each layer (230). At this time, the hole formed in the double-sided adhesive tape remains as an empty space when the paper of each layer is bonded, thereby interfering with the vertical movement (especially, movement in an upward direction) of the fluid. Accordingly, a hydrophilic material (such as paper or cellulose powder) to fill these holes is separately prepared (250). Thereafter, the three-dimensional paper-based microfluidic device is completed by aligning and then bonding the components prepared in the above process. The three-dimensional paper-based microfluidic device may be manufactured by the above method, but the process is complicated, requires a lot of time and labor, and should precisely control the paper of each layer and the adhesive tape layer, which leads to an increase in production cost.

In order to solve such a problem, the present inventors have proposed a method of manufacturing a three-dimensional paper-based microfluidic device by printing wax on double sides of one sheet of paper, and heat-treating the paper as shown in FIG. 3 in Korean Patent No. 10-1493051. The method is a very simplified method compared to the conventional method, and an innovative method in that the three-dimensional paper-based microfluidic device may be simply and economically manufactured. However, it is difficult to precisely align the wax printed patterns on the front and rear sides even when the double sides are printed, and as the shape of the three-dimensional structure becomes more complicated, defects due to alignment errors become a problem. Moreover, there is a problem in that when the paper itself has an atypical shape other than a rectangular shape, it is difficult to print the wax pattern on both sides.

### Related Art Document

### Patent Document

(Patent Document 1) Korean Patent Application Laid-Open No. 10-2010-0127301 (Dec. 3, 2010) (Patent Document 2) Korean Patent No. 10-1493051 (Feb. 6, 2015)

### SUMMARY OF THE DISCLOSURE

The present disclosure is to solve the problem in manufacturing a microfluidic device in which a channel is formed using a hydrophobic wax in a hydrophilic porous substrate, and an object of the present disclosure is to provide a method of manufacturing a microfluidic device capable of forming a channel of a desired shape even on an atypical substrate.

In particular, an object of the present disclosure is to provide a method of manufacturing a microfluidic device capable of solving the problem of high defect rate due to misalignment of a wax pattern on the front and rear sides when a three-dimensional microfluidic device is manufactured.

Furthermore, an object of the present disclosure is to provide a method of manufacturing a microfluidic device capable of simply controlling a shape of a wax pattern at the interface of the device.

In order to achieve the object, the present disclosure relates to a method of manufacturing a microfluidic device in which a microfluidic channel is formed by a wax within a hydrophilic porous substrate, the method including: stacking and then heat-treating a transfer film on which a mirror image of a wax pattern is formed to form a microchannel and the substrate.

The method of manufacturing the microfluidic device according to the present disclosure may be applied more usefully, particularly when manufacturing a three-dimensional microfluidic device. Specifically, the method of manufacturing the microfluidic device according to the present disclosure may be characterized by forming the three-dimensional microchannel within one substrate by thermally transferring a wax pattern to each of both sides of the substrate from two transparent transfer films when manufacturing the three-dimensional microfluidic device, thereby solving the alignment problem of the wax patterns of both sides. In the present disclosure, the term “thermally transferring” means that heat is applied in a state in which the wax-formed surface of the transfer film comes into contact with the substrate and the molten wax is transferred to the substrate. In this heat transfer process, the wax is not only transferred to the surface of the substrate, but also partially permeates into pores of the substrate to form a microchannel using a hydrophobic wax as an interface within the substrate.

The substrate may be a paper, a porous metal mesh, a nonwoven fabric, a hydrophilic polymer membrane, a sponge, or a fabric, and may have a predetermined two-dimensional shape. Usually, a wax pattern may be printed relatively easily using a wax printer on a rectangular substrate of a specific standard, but it is difficult to print the wax pattern on an atypical substrate other than a rectangular shape or an inflexible substrate by a printer, and particularly, it is more difficult to align and print the patterns of both sides. In particular, the present disclosure may be more usefully used when the substrate has an atypical two-dimensional shape.

It is possible to adjust a cross-sectional shape of a channel formed by the wax at an interface of the substrate on the substrate having the atypical two-dimensional shape.

As described above, according to the method of manufacturing the microfluidic device by transfer according to the present disclosure, it is possible to form the microchannel according to the wax pattern regardless of the shape of the substrate, and easily control the cross-sectional shape at the interface of the substrate.

According to the method of manufacturing the microfluidic device according to the present disclosure, it is possible to easily align the wax pattern printed on both sides of the paper when the transparent transfer film is used to greatly reduce the defect rate and more precisely form the microchannel when the three-dimensional microfluidic device is manufactured, thereby being usefully used in manufacturing the three-dimensional microfluidic device such as diagnosis and analysis devices or micro-robots with complicated structure.

In particular, according to the method of manufacturing the microfluidic device according to the present disclosure, it is possible to easily align the wax pattern even after the substrate is processed to the predetermined shape in advance when the shape of the substrate is the atypical shape, thereby expanding the application field of the three-dimensional microfluidic device.

### BRIEF DESCRIPTION OF THE DRAWINGS

FIG. 1 is a schematic view of one-dimensional, two-dimensional, and three-dimensional microfluidic devices.

FIGS. 2 and 3 are views showing a process of manufacturing a three-dimensional microfluidic device according to the related art.

FIG. 4 is a flowchart showing a process of manufacturing a three-dimensional microfluidic device according to one aspect of the present disclosure.

FIG. 5 is a schematic view showing the process of manufacturing the microfluidic device according to the method of FIG. 4.

FIG. 6 is a flowchart showing a process of manufacturing a three-dimensional microfluidic device according to another aspect of the present disclosure.

FIG. 7 is a schematic view showing the process of manufacturing the microfluidic device according to the method of FIG. 5.

FIG. 8 and FIG. 9(a), FIG. 9(b), FIG. 9(c) are schematic views showing a process of forming a microchannel having a specific structure according to one embodiment of the present disclosure.

FIG. 10 shows a lab-on-paper chip according to one embodiment of the present disclosure.

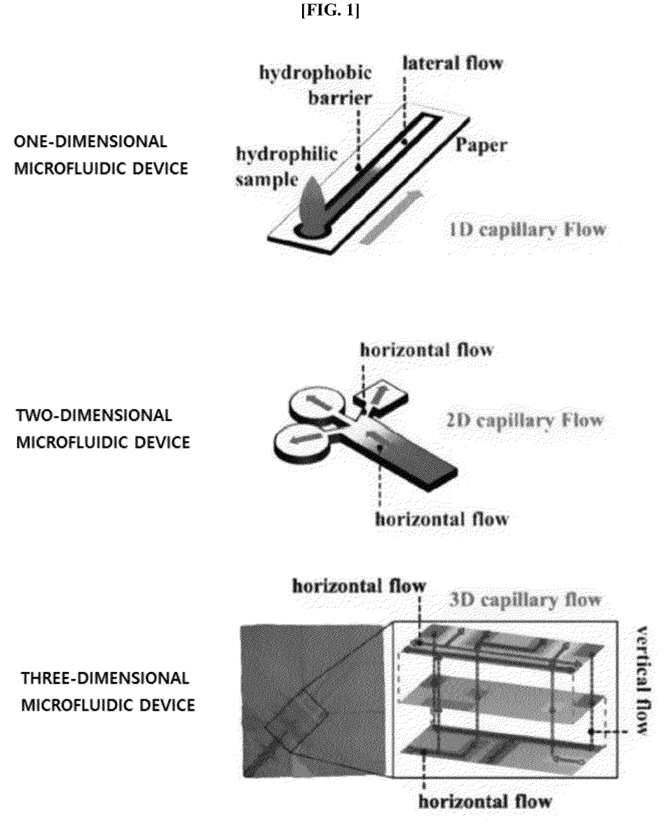

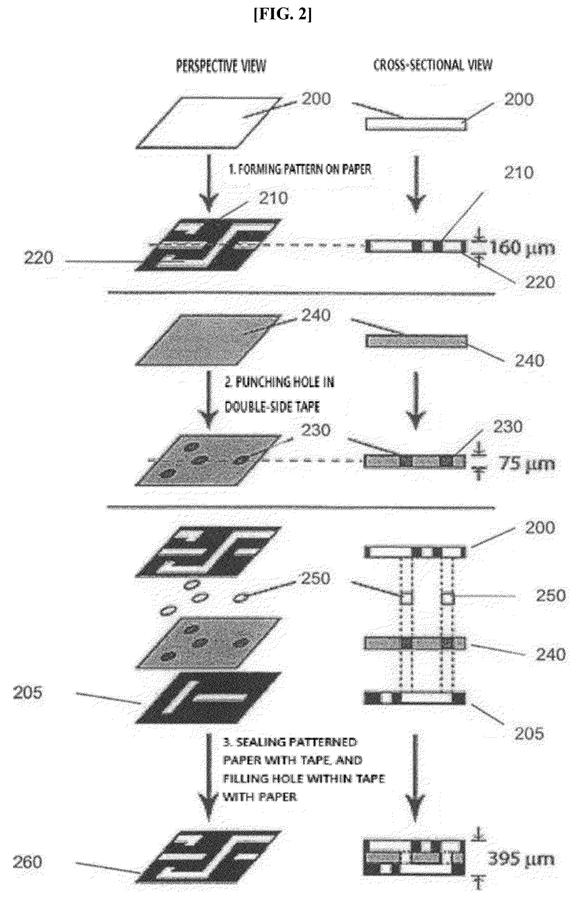

### DETAILED DESCRIPTION

Hereinafter, the present disclosure will be described in more detail with reference to the accompanying drawings. However, this description is only examples for easily describing the content and scope of the technical spirit of the present disclosure, and the technical scope of the present disclosure is not limited or changed thereby. It will go without saying that various modifications and changes by those skilled in the art are possible without departing from the scope of the technical spirit of the present disclosure based on these examples. In addition, in the description of the disclosure, when it is determined that a detailed description of a known technology related to the disclosure may unnecessarily obscure the gist of the disclosure, the detailed description thereof will be omitted.

As described above, the present disclosure relates to a method of manufacturing a microfluidic device in which a microchannel is formed by wax on a single hydrophilic porous substrate. The microfluidic device enables a lateral flow of a fluid due to the porous nature of the substrate, and the hydrophobic wax forms the boundary of the microchannel within the microfluidic device.

Unlike Korean Patent No. 10-1493051 of the present inventors conventionally disclosing that a wax pattern for forming a microchannel is formed by printing through a wax printer and subsequent heat treatment, the present disclosure is characterized by a method including an operation of stacking and then heat-treating a transfer film on which a mirror image of the wax pattern is formed and the substrate. In the heat-treatment process, the wax is transferred from the transfer film to the substrate, and at the same time, melted into pores of the substrate. A depth of permeating into the pores in the same transfer process is affected by a melting viscosity of the wax, and the depth of the channel may be adjusted by using this property, so that it is possible to manufacture a microfluidic device with a more complicated structure using various waxes with different melting viscosities. Since this content is disclosed in Korean Patent No. 10-1662802 of the present inventors, a detailed description thereof will be omitted. In the related art, since various materials and properties of the transfer film have been already studied according to the material to be transferred, those skilled in the art will easily select a film suitable for transferring the wax. Since the present disclosure does not relate to the transfer film itself, but to a method of manufacturing a microfluidic device through transfer, a detailed description of the transfer film itself will be also omitted.

First, a method of manufacturing the microfluidic device of the present disclosure through transfer may be usefully used in the method of manufacturing a three-dimensional microfluidic device. According to a method disclosed in Korean Patent No. 10-1493051, a microfluidic device may be simply manufactured by printing a wax pattern for forming a microchannel on both sides of a substrate and then heat-treating the wax pattern. However, it is not easy to accurately align and print the pattern at locations corresponding to both sides of the substrate, and defects due to alignment errors occur even when the double-sided printing method in which both sides are printed at the same time is used. In order to solve this problem, according to the present disclosure, a three-dimensional microchannel is formed in a single substrate by thermally transferring a wax pattern on both sides of the substrate from two transparent transfer films, respectively. The transparent film may prevent the occurrence of defects by facilitating the alignment of the wax pattern.

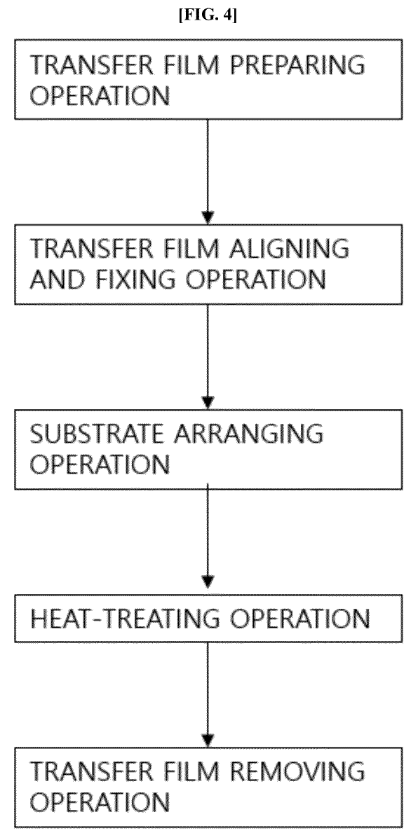

The method of manufacturing the microfluidic device in which the three-dimensional microchannel using the transparent transfer film is formed may use, for example, the method of FIG. 4 that aligns and then fixes two transparent films in advance and arranges and heat-treats the substrate therebetween. Specifically, the method of FIG. 4 includes: a transfer film preparing operation (A) of preparing a transparent transfer film in which mirror images of wax patterns to be transferred on both sides of a substrate in order to form a three-dimensional channel are formed, respectively; a transfer film aligning and fixing operation (B) of aligning and fixing the transfer films so that wax-formed surfaces face each other; a substrate arranging operation (C) of forming a layered structure by arranging a hydrophilic porous substrate between the transfer films; a heat-treating operation (D) of forming a three-dimensional microchannel on the substrate while transferring the wax by applying heat to the layered structure; and a transfer film removing operation (E) of removing the transfer film from the layered structure.

Hereinafter, each operation will be described in more detail.

First, the transfer film preparing operation (A) is an operation of preparing a set of transfer films for forming a three-dimensional channel. In order to form the three-dimensional channel, first, the wax patterns to be formed on both sides of the substrate, respectively should be designed. Compared to the related art disclosing that the wax patterns to be designed are printed directly on both sides of the substrate, according to the present disclosure, since the wax patterns are transferred to both sides of the substrate from two transfer films, the transfer films in which mirror images of the wax patterns are formed on the two transfer films, respectively are prepared. At this time, the transfer film is characterized by being transparent.

The transfer film aligning and fixing operation (B) is an operation of aligning and fixing the set of transfer films so that the wax-formed surfaces face each other.

According to the present disclosure, since the transfer film is transparent, the two transfer films may be precisely aligned even when the mirror images of the wax patterns to be formed on both sides of the substrate are formed on the two transfer films. In the present disclosure, the term “transparent” means the degree to which the shapes of the other layers may be identified in the state in which the films are stacked, and includes translucency. For example, when a transparency in a visible light region is 50% or more, there will be no difficulty in alignment, but it goes without saying that the higher the transparency, the easier the alignment. In addition, even when the transparency in the entire visible ray region is 50% or less, when the transmittance in the wavelength region corresponding to the color of the wax is high, and thus identification is easy, it conforms to the purpose of the present disclosure.

In the present disclosure, the term “aligning” means adjusting the locations so that the locations of the wax patterns to be formed on the substrate correspond to each other. Recognizing the wax pattern formed on the opposite transfer film through the transparent transfer film may be done with the naked eye, but when more precise alignment is required, an instrument such as a microscope may be used. When the alignment is completed, the two transfer films are fixed so that the alignment is not disturbed. The fixation may be most simply performed by using tape, pins, tongs, etc., and the fixing method is not limited thereto.

The operation (C) is a substrate arranging operation, and is an operation of fitting and arranging a hydrophilic porous substrate between the transfer films. Since the transfer film is already fixed in an aligned state in the previous operation, the aligned state may be maintained even when the substrate is inserted between the transfer films. However, for example, when there is a risk of misalignment when the substrate is arranged because the thickness of the substrate is large, a transparent alignment film may be used in this operation. In other words, after being stacked in a state of the transfer film-the alignment film-the transfer film in which the alignment film is inserted between two transfer films, the transfer film is fixed, and then the alignment film may be substituted with the substrate. At this time, a thickness of the alignment film is preferably similar to the thickness of the substrate. The alignment film does not affect the alignment of the transfer film because the alignment film is transparent, and prevents alignment errors caused by arranging the substrate in the aligned state.

When there is a region where two transfer films directly overlap in the layered structure formed in this operation, that is, when there is a region where there is no substrate therebetween, an alignment mark may be displayed in the region. The alignment mark makes it possible to read whether the alignment errors occur when the substrate is arranged in advance.

The alignment film may have a shape in which one side direction is longer than the transfer film so that the alignment film is aligned between the two transfer films and then easily removed, and the other side direction is shorter than the transfer film so that the transfer film is easily fixed. Since the transfer films directly overlap each other on both ends in a direction of the side at which the alignment film is short, only the transfer films may be fixed, and the alignment film may be easily removed by holding and pulling the side at which the alignment film is long after the transfer film is fixed. In addition, by connecting one end of the side at which the alignment film is long to the substrate and holding and pulling the other end, the alignment film is removed and may be substituted with the substrate at the removed location instead. The alignment film is sufficient when the size of the alignment film is a size that may maintain an interval between the transfer films, and does not have to correspond to the size of the substrate.

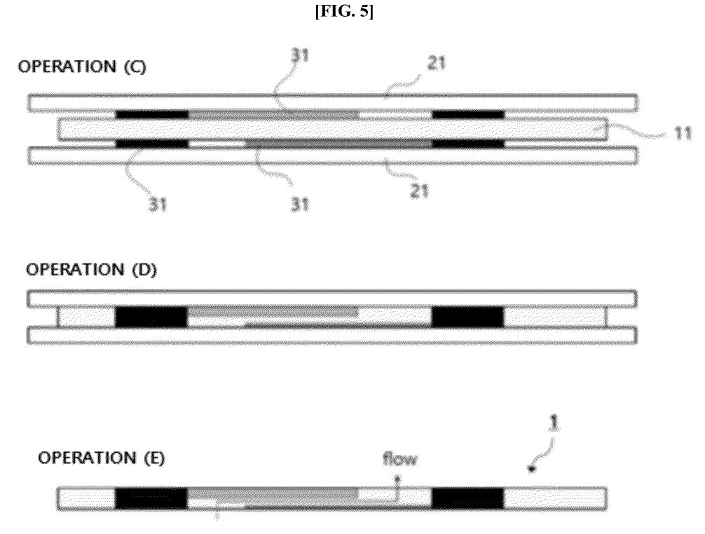

The heat-treating operation (D) is an operation of transferring the wax to the substrate from the transfer film by heat-treating the layered structure of the transfer film-the substrate-the transfer film, and then permeating the transferred wax into pores within the substrate. FIG. 5 is a view describing the operation (C) to the operation (E) below, and shows that the wax permeates into the substrate in the heat-treating process, and the degree of permeation may be different depending on a melting viscosity of the wax. When the waxes transferred to both sides permeate into both sides of the substrate and meet each other, a wall of the microchannel is formed within the substrate, and when the waxes transferred to both sides permeate into both sides of the substrate but do not meet, the wall is formed on the top and bottom of a cross section of the substrate by the wax and thus the microchannel through which the fluid moves in a cross-section direction of the substrate is formed. When the wax is transferred only to the top or bottom of the substrate and permeates into the substrate, a channel through which the fluid moves in a vertical direction from the top or bottom of the substrate is formed. In addition, there are several other application types, but it may be applied by applying the related art depending on the type of the microfluidic device.

The transfer film removing operation (E) is an operation of removing a transfer film 21 and obtaining a microfluidic device 1 as a wax 31 is transferred to a substrate 11 from the transfer film 21 and permeates into pores and the microchannel due to the wax 31 is completed in the heat-treating operation (D). In some cases, the microfluidic device is stored and distributed in a state in which the transfer film is attached and the transfer film may also be removed just before the microfluidic device is used. In this case, the transfer film may serve as a protective layer for preventing contamination of the microfluidic device.

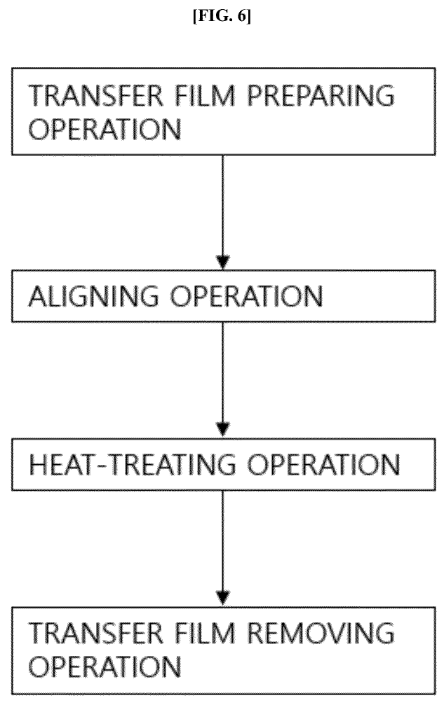

In some cases, the alignment of the transfer film may not be affected even when the substrate is inserted between the transfer films. For example, when the substrate is transparent or has a shape corresponding to the wax pattern, the alignment of the transfer film will not be affected even when the substrate is inserted between the transfer films. In this case, rather than aligning the transfer films in advance and then fitting the substrate between the transfer films, it may be more efficient to arrange and then align the transfer films in the form of the transfer film-the substrate-the transfer film from the beginning. Specifically, as shown in FIG. 6, the microfluidic device may be manufactured by a method including: a transfer film preparing operation (A′) of preparing a transparent transfer film on which mirror images of wax patterns to be transferred to both sides of a substrate in order to form a three-dimensional channel are formed, respectively; an aligning operation (B′) of aligning and fixing a layered structure in which a hydrophilic porous substrate is arranged between the transfer films arranged so that wax-formed surfaces face each other; a heat-treating operation (C′) of transferring the wax and at the same time, forming the three-dimensional microchannel on the substrate by applying heat to the layered structure; and an operation of removing the transfer film (D′). The method is performed by the operation (B′) by combining the operations (B) and (C) in the exemplary method described above, and the descriptions of the corresponding operations (A), (D), and (E) may be applied to detailed descriptions of the operations (A′), (C′), and (D′) in the same way. In addition, the operation (B′) may align the transfer film-the substrate-the transfer film at once, but it goes without saying that the method may be sequentially performed, including an operation of aligning and fixing the hydrophilic porous substrate on a wax-formed surface of one of the transfer films (a); and an operation of aligning and fixing a wax surface of the other transfer film on the fixed substrate to face the substrate.

As described in the second of Background art, the microfluidic device according to the present disclosure may use the lateral flow of the fluid through pores in the microchannel, and any substrate may be used as long as it exhibits hydrophilicity and porosity. A representative example of the substrate is a paper, and a porous metal mesh, a nonwoven fabric, a hydrophilic polymer membrane, a sponge, a fabric, etc. may also be used likewise, but the present disclosure is not limited thereto. According to the method of the present disclosure, printing using a conventional printer is limited to a flexible material such as paper, whereas the microfluidic device may be manufactured without limitation even when a substrate of an inflexible material as well as a flexible substrate is used. In addition, the wax pattern may be formed on the surface of the substrate using the transfer film that exhibits flexibility even when the inflexible substrate does not exist on a single plane and is bent.

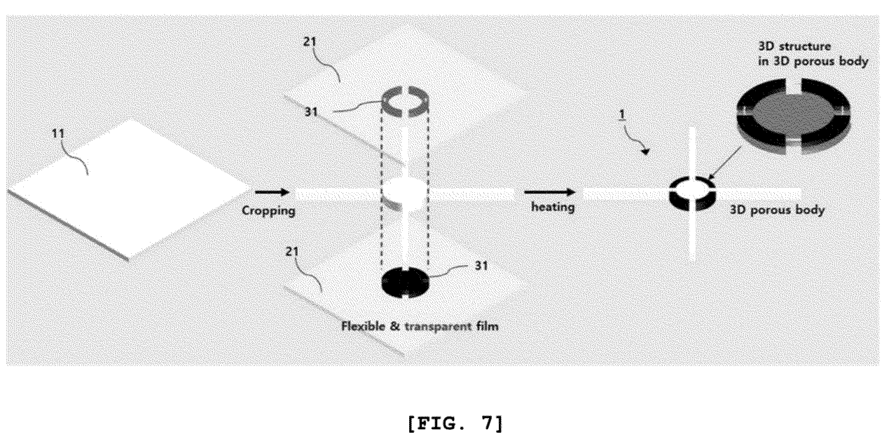

In particular, the method may be usefully used when the substrate has a predetermined atypical two-dimensional shape. Even when the substrate does not meet a separate standard, alignment using double-sided printing may be attempted when the substrate has a formalized rectangular shape, but the printing itself using the printer may be difficult when the substrate has the atypical shape other than the rectangular shape. Once the wax pattern is formed and then cut into a desired shape, an alignment problem occurs when the wax pattern is cut into the corresponding shape again. Accordingly, for example, the substrate may be prepared by being cut into a predetermined shape using a cutting printer and then the method according to the present disclosure may be applied to form the microchannel by the wax, thereby solving the problem according to the alignment. FIG. 7 shows a schematic view in which the method is applied to the atypical substrate. In FIG. 7, a part of the shape of the substrate matches with a shape of an oil pattern formed on a lower transfer film and thus alignment is easy. When the substrate has an atypical shape, a region where the transfer films overlap each other occurs, so that an alignment mark may be additionally formed on the transfer film and used for alignment.

The microfluidic device according to the present disclosure may be used to control the shape of the wax at the boundary of the longitudinal cross section of the substrate. The printing of the wax by the printer may form the wax pattern only on the surface of the substrate, and subsequently, the microchannel is formed by melting the wax formed on the substrate by heat treatment and permeating the wax into the substrate. On the other hand, since the microchannel through transfer is formed by melting and permeating the wax layer formed on the transfer film into the substrate in the heat-treatment process, the size of the wax pattern is not limited by the size of the paper, and by using the above, the shape of the wax at the boundary of the longitudinal cross section of the substrate may be controlled.

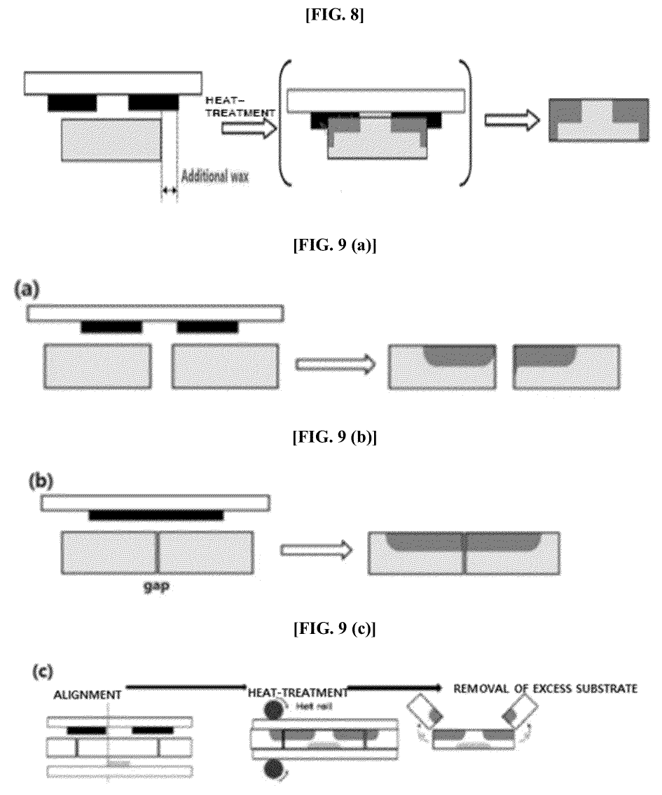

For example, in order to form a sidewall at the boundary (edge) of the microfluidic device, the wax patterns may be formed on both sides and the waxes permeating into the substrate from both sides according to the heat-treatment meet each other so that the side wall is formed. Alternatively, there is also a method of forming the pattern with the wax having low melting viscosity on the cross section so that the wax permeates into a lower surface of the substrate upon heat-treatment, but when the melting viscosity of the wax is too low, the degree of diffusion also increases, so that it should be considered that the degree of an increase in the width of the wax pattern also increases upon heat-treatment. The present disclosure provides a method of forming a wax sidewall at the boundary of the substrate by forming the wax pattern of the transfer film up to the outside of the interface of the substrate. As may be seen from the schematic view of FIG. 8, the wax formed on the transfer film is melted by the heat-treatment to permeate through a contact surface with the substrate. However, the wax additionally formed on the outside of the substrate flows along the boundary of the substrate because it does not come into contact with the substrate, and as a result, the sidewall is formed at the boundary of the substrate. According to the method of the present disclosure, there is an advantage in that the sidewall may be formed at the boundary of the substrate even when the wax pattern is printed at only one side without forming the wax pattern at both sides.

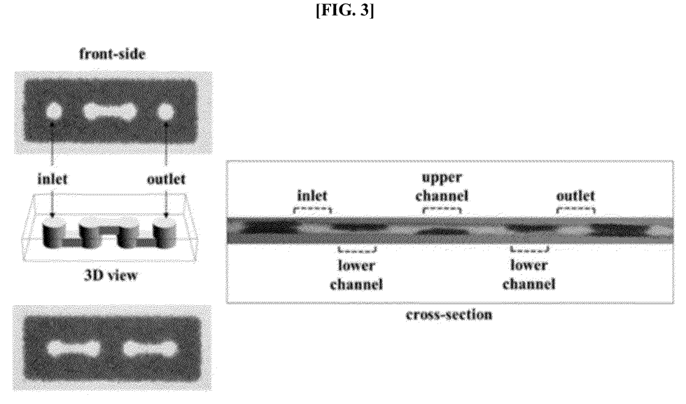

The schematic views of FIGS. 5 and 8 show that the shape of the wax layer is an accurately rectangular shape within the microfluidic device for convenience. However, in reality, as may be confirmed from the cross-sectional image of FIG. 3, since a diffusion occurs as the wax is melted and permeates into the substrate, the end has a curvature that is not a right angle in a state in which the wax slightly spreads more than the pattern. As shown in (a) of FIG. 9, when the wax is sufficiently far from the boundary of the substrate at the end of the substrate, a cross section with the same curvature as that of a non-boundary portion is formed, but when the wax approaches the boundary, some curvature is formed, or when the wax is too close to the boundary, the wax not diffused from the boundary to the side flows down. In particular, for a micro-robot, it is necessary to manufacture the microfluidic device having the shape of the channel having a straight end.

Accordingly, the present disclosure provides the method of forming the channel having the straight cross section at the boundary of the substrate using a cutting gap. Referring to (b) of FIG. 9, after the cutting gap is formed between a region A and a region B of the substrate, a wax pattern of the transfer film is formed in parts of the region A and the region B including the cutting gap and then heat-treated. When the cutting gap is small enough, the wax is not introduced into the gap and acts as if the two regions are attached upon heat-treatment, so that it is possible to form the straight pattern. When the cutting gap is too large, the region A and the region B serve as separate regions due to the cutting gap, so that the induction of the shape as shown on the right side of (a) may be generated. Accordingly, it is preferable that a width of the cutting gap is 0 (cutting only and substantially no gap) to 1 mm.

(c) of FIG. 9 shows a process of manufacturing a three-dimensional microfluidic device using the cutting gap, and first, the process aligns and heat-treats the stacked structure of the transfer film-the substrate-the transfer film using the substrate on which the cutting gap is formed to form the channel by the wax. At this time, it is shown that the heat-treatment is performed by using a roller, but it goes without saying that this is only illustrative and the present disclosure is not limited thereto. When the wax permeates into the substrate by heat-treatment, the microfluidic device may be manufactured by removing the excess substrate.

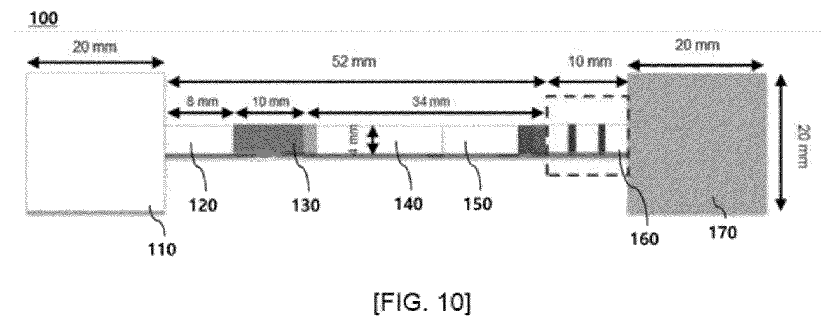

FIG. 10 shows a lab-on-paper chip according to the present disclosure.

In FIG. 10, a lab-on-paper chip 100 according to the present disclosure includes a plurality of pads, and the characteristics of each pad are as follows.

A disease or fungal infection diagnosis system according to the present disclosure is based on lab-on-paper chip technology, and when the disease or fungal infection diagnosis system according to the present disclosure is used, a nucleic acid material may be purified while moving to a reaction pad 140 even without purifying a separate nucleic acid and directly applied to an amplification reaction, and multiple target nucleic acids may be simultaneously detected and related diseases may be diagnosed by applying a single sample. In order to realize this, a structure for detecting the nucleic acid according to the present disclosure includes a buffer pad 110, a sample pad 130, a first connection pad 120, a reaction pad 140, a heating pad 141, a blocking pad 142, a second connection pad 150, a detection pad 160, and an absorption pad 170 as components.

The sample pad 130 may be a pad for receiving a biological sample, and the buffer pad 110 may be a pad disposed in contact with the sample pad 130 and receiving a rehydration buffer solution.

The reaction pad 140 includes a primer capable of being specifically bound to the target nucleic acid and a reagent for an isothermal amplification reaction (LAMP) and may be connected to the sample pad 130, and the detection pad 160 may be connected to the reaction pad 140 and may acquire the amplified target nucleic acid from the isothermal amplification reactant.

In one example, the reaction pad 140 proceeds the isothermal amplification reaction (LAMP), and the flow of the sample passing through the reaction pad 140 should be partially blocked to perform the isothermal amplification reaction (LAMP), or a flow rate thereof should be adjusted for the isothermal amplification reaction (LAMP).

To this end, the reaction pad 140 may align and thermally treat the stacked structure of the transfer film-substrate (reaction pad)-transfer film through the manufacturing process of the microfluidic device according to the present disclosure to form a flow path by wax. When the flow path is formed by wax as described above, a movement speed of the fluid due to the capillary phenomenon may be adjusted. By adjusting the moving speed of the fluid as described above, it is possible to increase the efficiency of the isothermal amplification reaction (LAMP) in the reaction pad 140.

In addition, as described above, since the microfluidic device according to the present disclosure may be used to control a shape of the wax at the boundary of the longitudinal cross section of the substrate, and for example, a side wall may be formed at the boundary (edge) of the microfluidic device, a wax-coated opening/closing area may be formed on the second connection pad 150 disposed in contact with the reaction pad 140 using the above. The opening/closing area can prevent the loss of the unreacted dielectric material in the sample by blocking the movement of the isothermal amplification reactant of the reaction pad 140, then melting the coating when the second connection pad 150 is heated, and laterally moving the isothermal amplification reactant again.

What is claimed is:

1. A method of manufacturing a microfluidic device in which a microchannel by a wax is formed within one hydrophilic porous substrate, the method comprising:
stacking and then heat-treating a transfer film on which a mirror image of a wax pattern for forming the microchannel is formed and the substrate.

2. The method of claim 1,
wherein a three-dimensional microchannel is formed within one substrate by thermally transferring the wax patterns to each of both sides of the substrate from two transparent transfer films.

3. The method of claim 2, comprising:
(A) a transfer film preparing operation of preparing the transparent transfer film on which mirror images of the wax patterns to be transferred to both sides of the substrate in order to form a three-dimensional channel are formed, respectively;
(B) a transfer film aligning and fixing operation of aligning and fixing the transfer film so that wax-formed surfaces face each other;
(C) a substrate arranging operation of forming a layered structure by arranging the hydrophilic porous substrate between the transfer films;
(D) a heat-treating operation of forming the three-dimensional microchannel on the substrate while transferring the wax by applying heat to the layered structure; and
(E) a transfer film removing operation of removing the transfer film from the layered structure.

4. The method of claim 3,
wherein in the operation (C), the transfer films are aligned in a state in which a transparent alignment film is inserted between the transfer films, and only the transfer films other than the alignment film are fixed, and
in the operation (D), the alignment film is substituted with the substrate.

5. The method of claim 3,
wherein one side direction of the alignment film is longer than the transfer film, and the other side direction thereof is shorter than the transfer film.

6. The method of claim 2, comprising:
(A′) a transfer film preparing operation of preparing the transparent transfer film on which mirror images of wax patterns to be transferred to both sides of the substrate in order to form a three-dimensional channel are formed, respectively;
(B′) an aligning operation of aligning and fixing a layered structure in which the hydrophilic porous substrate is arranged between the transfer films arranged so that wax-formed surfaces face each other;
(C′) a heat-treating operation of forming the three-dimensional microchannel on the substrate while transferring the wax by applying heat to the layered structure; and
(D′) removing the transfer film.

7. The method of claim 6, wherein the operation (B′) includes:
(a) an operation of aligning and fixing the hydrophilic porous substrate on the wax-formed surface of one of the transfer films; and
(b) an operation of aligning and fixing the wax surface of the other of the transfer films on the fixed substrate to face the substrate.

8. The method of claim 3,
wherein when there is a region where two transfer films directly overlap each other in the layered structure, there is an alignment mark in the corresponding region.

9. The method of claim 1,
wherein the hydrophilic porous substrate is a paper, a porous metal mesh, a nonwoven fabric, a hydrophilic polymer membrane, a sponge or a fabric.

10. The method of claim 1,
wherein the substrate has a predetermined atypical two-dimensional shape.

11. The method of claim 10,
wherein the wax pattern of the transfer film is formed up to the outside of an interface of the substrate to form a partition wall at a boundary of the substrate.

12. The method of claim 10,
wherein a cutting gap of 0 to 1 mm is formed at the boundary of the substrate,
the wax pattern of the transfer film is formed up to the outside of the interface of the substrate, and a channel having a straight cross section is formed at the boundary of the substrate by removing the cutting gap after transfer.
